(19) United States
(12) Patent Application Publication
(10) Pub. No.: US 2025/0015176 A1
(43) Pub. Date: Jan. 9, 2025

(54) SEMICONDUCTOR DEVICE

(71) Applicant: ROHM CO., LTD., Kyoto-shi (JP)

(72) Inventor: Masaki NAGATA, Kyoto-shi (JP)

(73) Assignee: ROHM CO., LTD., Kyoto-shi (JP)

(21) Appl. No.: 18/895,395

(22) Filed: Sep. 25, 2024

Related U.S. Application Data
(63) Continuation of application No. PCT/JP2023/002430, filed on Jan. 26, 2023.

(30) Foreign Application Priority Data
Mar. 28, 2022 (JP) 2022-051510

(51) Int. Cl. H01L 29/78; H01L 29/06; H01L 29/40

(52) U.S. Cl. CPC H01L 29/7813; H01L 29/0696; H01L 29/407

(57) ABSTRACT

A semiconductor device includes a semiconductor layer; a trench formed in the semiconductor layer and including a side wall, an insulation layer formed on the semiconductor layer; and a gate electrode arranged in the trench. The insulation layer includes a gate insulation portion located between the semiconductor layer and the gate electrode, and covering the side wall of the trench. The gate electrode includes a first conductive portion contacting the gate insulation portion, and a second conductive portion including a side surface contacting the first conductive portion. The first conductive portion is formed from polysilicon, and the second conductive portion is formed from metal.

### CROSS-REFERENCE TO RELATED APPLICATIONS

The present application is a bypass continuation of International Patent Application No. PCT/JP2023/002430, filed on Jan. 26, 2023, which claims priority to Japanese Patent Application No. 2022-051510, filed on Mar. 28, 2022, the entire disclosures of these applications are incorporated herein by reference.

### BACKGROUND

### 1. Field

The present disclosure relates to a semiconductor device.

### 2. Description of Related Art

A known MISFET has a trench gate structure including a gate trench, an insulation layer, a bottom side electrode, and an open-side electrode (refer to, for example, Japanese Laid-Open Patent Publication No. 2020-072158). Japanese Laid-Open Patent Publication No. 2020-072158 discloses that the open-side electrode functions as a gate electrode and contains conductive polysilicon.

### BRIEF DESCRIPTION OF THE DRAWINGS

FIG. 1 is a schematic plan view of an exemplary semiconductor device in accordance with a first embodiment.

FIG. 2 is a schematic cross-sectional view of a gate trench taken along line F2-F2 in FIG. 1.

FIG. 3 is a partially enlarged view of FIG. 2.

FIG. 4 is a schematic cross-sectional view of a gate trench taken along line F4-F4 in FIG. 1.

FIG. 5 is a schematic cross-sectional view of an exemplary semiconductor device in accordance with a second embodiment.

FIG. 6 is a schematic cross-sectional view of an exemplary semiconductor device in accordance with a third embodiment.

FIG. 7 is a schematic cross-sectional view showing a modified example of a gate electrode.

FIG. 8 is a schematic cross-sectional view showing a modified example of a gate contact.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a semiconductor device in accordance with the present disclosure will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of exemplary methods, apparatuses, and/or systems in accordance with the present disclosure. This detailed description is illustrative and is not intended to limit embodiments of the present disclosure or the application and use of the embodiments.

### First Embodiment

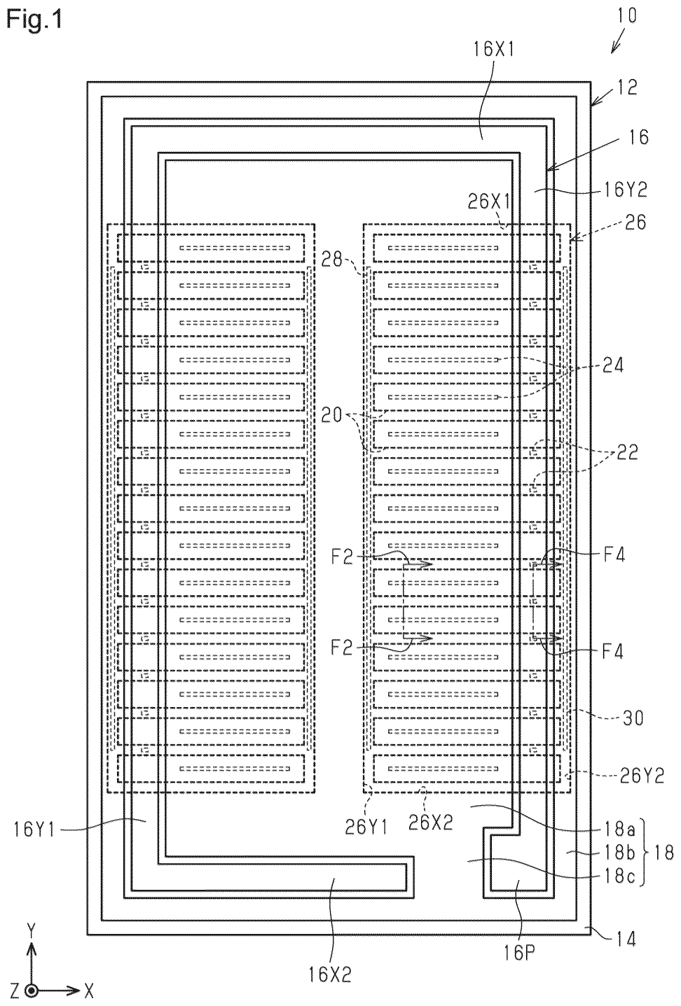

FIG. 1 is a schematic plan view of an exemplary semiconductor device 10 in accordance with a first embodiment. In the present disclosure, the X-axis, Y-axis, and Z-axis are orthogonal to one another as shown in FIG. 1. The term “plan view” as used in this specification is a view of the semiconductor device 10 taken in the Z-axis direction. Unless otherwise indicated, the term “plan view” will refer to a view of the semiconductor device 10 taken from above along the Z-axis.

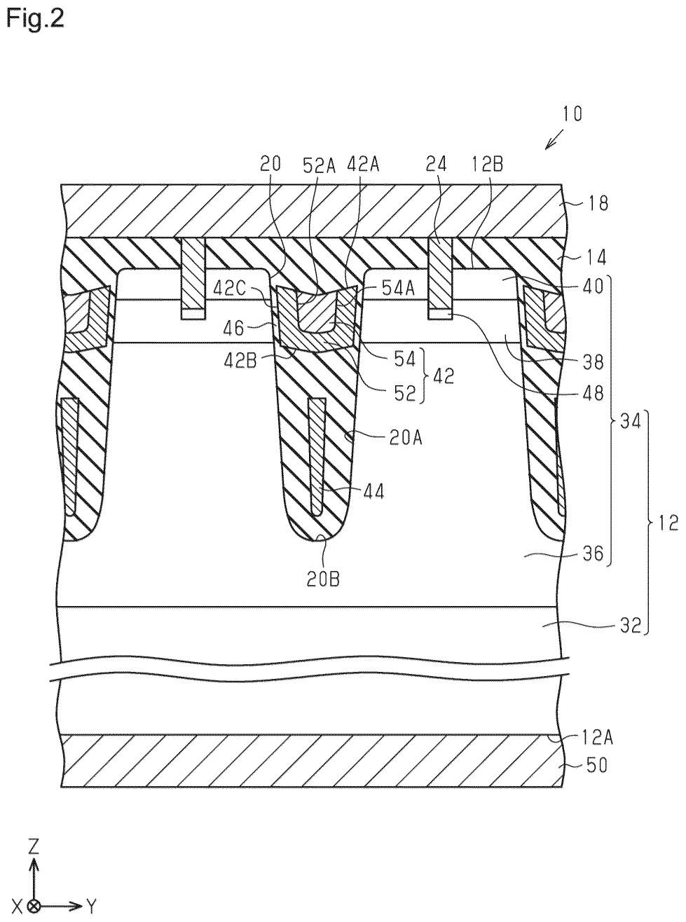

The semiconductor device 10 is, for example, a metal insulator semiconductor field effect transistor (MISFET) having a trench gate structure. The semiconductor device 10 includes a semiconductor layer 12 and an insulation layer 14 formed on the semiconductor layer 12. In one example, the semiconductor layer 12 may be formed from silicon (Si). As will be described later with reference to FIG. 2, the semiconductor layer 12 includes a first surface 12A and a second surface 12B opposite to the first surface 12A. In FIG. 1, the Z-axis direction may be orthogonal to the first surface 12A and the second surface 12B of the semiconductor layer 12. The semiconductor layer 12 is covered by the insulation layer 14. Thus, FIG. 1 shows only the rectangular contour of the semiconductor layer 12. In one example, the insulation layer 14 may be formed by a film of silicon oxide (SiO₂). In addition to or instead of the silicon oxide film, the insulation layer 14 may include a layer formed from an insulation material that differs from SiO₂, for example, silicon nitride (SiN).

### Exemplary Planar Layout of Semiconductor Device

The semiconductor device 10 may further include a gate interconnection 16, which is formed on the insulation layer 14, and a source interconnection 18, which is formed on the insulation layer 14. The source interconnection 18 is insulated from the gate interconnection 16. The gate interconnection 16 and the source interconnection 18 may be formed from at least one of titanium (Ti), nickel (Ni), gold (Au), silver (Ag), copper (Cu), aluminum (Al), a copper alloy, and an aluminum alloy.

The gate interconnection 16 may generally extend along the outer edges of the semiconductor layer 12. In the example of FIG. 1, the gate interconnection 16 includes a first gate interconnection portion 16X1 and a second gate interconnection portion 16X2, which extend in the X-axis direction, and a third gate interconnection portion 16Y1 and a fourth gate interconnection portion 16Y2, which extend in the Y-axis direction. The first gate interconnection portion 16X1 is connected between one end of the third gate interconnection portion 16Y1 and one end of the fourth gate interconnection portion 16Y2. The second gate interconnection portion 16X2 is connected to the other end of the third gate interconnection portion 16Y1 but not to the other end of the fourth gate interconnection portion 16Y2. The gate interconnection 16 may further include a gate pad portion 16P. In the example of FIG. 1, the other end of the fourth gate interconnection portion 16Y2 is connected to the gate pad portion 16P.

The source interconnection 18 may include an inner source interconnection portion 18a, which is at least partially surrounded by the gate interconnection 16, and an outer source interconnection portion 18b, which surrounds the gate interconnection 16. The source interconnection 18 may further include a source connecting portion 18c connecting the part between the inner source interconnection portion 18a and the outer source interconnection portion 18b. In the example of FIG. 1, the gate interconnection 16 has the form of an open loop partially surrounding the inner source interconnection portion 18a. The source connecting portion 18c, which is located at the part where the loop of the gate interconnection 16 opens, connects the inner source interconnection portion 18a to the outer source interconnection portion 18b. In the example of FIG. 1, the source connecting portion 18c extends between the second gate interconnection portion 16X2 and the gate pad portion 16P. In another example, the loop of the gate interconnection 16 may be open at a different location. In a further example, the gate interconnection 16 may have the form of a closed loop in plan view.

The semiconductor device 10 further includes a gate trench 20 (also simply referred to as the trench 20) formed in the semiconductor layer 12. The gate trench 20 may be arranged to overlap both the gate interconnection 16 and the source interconnection 18 at least partially in plan view. The semiconductor device 10 may include multiple gate trenches 20, and some of the gate trenches 20 may be arranged parallel to one another and at equal intervals. In the example of FIG. 1, each gate trench 20 extends in the X-axis direction and intersects the third gate interconnection portion 16Y1 or the fourth gate interconnection portion 16Y2 in plan view.

The semiconductor device 10 may further include gate contact plugs 22 and source contact plugs 24 extending through the insulation layer 14. The gate contact plugs 22 are coupled to the gate interconnection 16. The gate contact plugs 22 may be arranged in a region where the gate trenches 20 intersect the gate interconnection 16 in plan view. The source contact plugs 24 are coupled to the source interconnection 18. Each source contact plug 24 extends parallel to the gate trenches 20 and is arranged between two of the gate trenches 20.

The semiconductor device 10 may further include terminal trenches 26 formed in the semiconductor layer 12. In the example of FIG. 1, each terminal trench 26 includes a first terminal trench portion 26X1 and a second terminal trench portion 26X2, which extend in the X-axis direction, and a third terminal trench portion 26Y1 and a fourth terminal trench portion 26Y2, which extend in the Y-axis direction. The gate trenches 20, which are arranged parallel to one another, are located between the first terminal trench portion 26X1 and the second terminal trench portion 26X2 in plan view. The third terminal trench portion 26Y1 overlaps the inner source interconnection portion 18a in plan view. Further, the fourth terminal trench portion 26Y2 overlaps the outer source interconnection portion 18b in plan view. The gate trenches 20 extend between and are in communication with the third terminal trench portion 26Y1 and the fourth terminal trench portion 26Y2. Thus, the gate trenches 20 overlap both the inner source interconnection portion 18a and the outer source interconnection portion 18b in plan view.

The semiconductor device 10 may further include first field plate contact plugs 28 and second field plate contact plugs 30 extending through the insulation layer 14. Each first field plate contact plug 28 is coupled to the inner source interconnection portion 18a. The first field plate contact plug 28 overlaps the corresponding third terminal trench portion 26Y1 in plan view. Each second field plate contact plug 30 is coupled to the outer source interconnection portion 18b. The second field plate contact plug 30 overlaps the corresponding fourth terminal trench portion 26Y2 in plan view.

The gate contact plugs 22, the source contact plugs 24, the first field plate contact plugs 28, and the second field plate contact plugs 30 may each be formed from any metal material. In one example, the contact plugs 22, 24, 28, and 30 may each be formed from at least one of tungsten (W), titanium (Ti), and titanium nitride (TiN).

The planar layout of the semiconductor device 10 is not limited to the example of FIG. 1. For example, the semiconductor device 10 does not have to include the terminal trenches 26. In such a case, the field plate conductor plugs 28 and 30 may be arranged to overlap the ends of the gate trenches 20. For example, the semiconductor device 10 may further include gate trenches 20 that extend in the Y-axis direction, and the first gate interconnection portion 16X1 and the second gate interconnection portion 16X2 may intersect the gate trenches 20 extending in the Y-axis direction. For example, the semiconductor device 10 does not have to include the source interconnection 18. In such a case, the field plate conductor plugs 30 may be arranged to overlap the ends of the gate trenches 20.

### Details of Gate Trench

With reference to FIG. 2, the gate trenches 20 of the semiconductor device 10 will now be described in detail. FIG. 2 is a schematic cross-sectional view of the semiconductor device 10 taken along line F2-F2 in FIG. 1.

The semiconductor layer 12 may include a semiconductor substrate 32 and an epitaxial layer 34 formed on the semiconductor substrate 32. In such a case, the semiconductor substrate 32 includes the first surface 12A of the semiconductor layer 12, and the epitaxial layer 34 includes the second surface 12B of the semiconductor layer 12. In one example, the semiconductor substrate 32 may be a Si substrate. The semiconductor substrate 32 corresponds to a drain region of the MISFET. The epitaxial layer 34 may be a Si layer that is epitaxially grown on the Si substrate. The epitaxial layer 34 may include a drift region 36, a body region 38 formed on the drift region 36, and a source region 40 formed on the body region 38. The source region 40 may include the second surface 12B of the semiconductor layer 12.

The drain region (semiconductor substrate 32) may be an n-type region containing n-type impurities. The drain region (semiconductor substrate 32) may have an n-type impurity concentration in a range from 1×10¹⁸ cm⁻³ to 1×10²⁰ cm⁻³, inclusive. The drain region (semiconductor substrate 32) may have a thickness in a range from 50 μm to 450 μm, inclusive.

The drift region 36 may be an n-type region containing n-type impurities at a lower concentration than the drain region (semiconductor substrate 32). The drift region 36 may have an n-type impurity concentration in a range from 1×10¹⁵ cm⁻³ to 1×10¹⁸ cm⁻³. The drift region 36 may have a thickness in a range from 1 μm to 25 μm, inclusive.

The body region 38 may be a p-type region containing p-type impurities. The body region 38 may have a p-type impurity concentration in a range from 1×10¹⁶ cm⁻³ to 1×10¹⁸ cm⁻³, inclusive. The body region 38 may have a thickness in a range from 0.2 μm to 1.0 μm, inclusive.

The source region 40 may be an n-type region containing n-type impurities at a higher concentration than the drift region 36. The source region 40 may have an n-type impurity concentration in a range from 1×10¹⁹ cm⁻³ to 1×10²¹ cm⁻³, inclusive. The source region 40 may have a thickness in a range from 0.1 μm to 1 μm, inclusive.

In the present disclosure, n-type is also referred to as a first conductivity type, and p-type is also referred to as a second conductivity type. The n-type impurities may be, for example, phosphorus (P), arsenic (As), or the like. The p-type impurities may be, for example, boron (B), aluminum (Al), or the like.

Each gate trench 20 includes an opening in the second surface 12B of the semiconductor layer 12 and has a depth in the Z-axis direction. The gate trench 20 extends through the source region 40 and the body region 38 of the semiconductor layer 12 to the drift region 36. The gate trench 20 includes a side wall 20A and a bottom wall 20B. The bottom wall 20B is adjacent to the drift region 36. The gate trench 20 may have a depth in a range from 1 μm to 10 μm, inclusive.

The side wall 20A of the gate trench 20 may extend in a direction orthogonal to the second surface 12B of the semiconductor layer 12 (Z-axis direction) or be inclined relative to the Z-axis direction. In one example, the side wall 20A may be inclined relative to the Z-axis direction so that the width of the gate trench 20 decreases toward the bottom wall 20B. Further, the bottom wall 20B of the gate trench 20 does not necessarily have to be flat and may be, for example, partially or entirely curved.

The semiconductor device 10 further includes a gate electrode 42 and a first field plate electrode 44 that are arranged in each gate trench 20. The gate electrode 42 may be an electrode to which gate voltage is applied, and the field plate electrode 44 may be an electrode to which reference voltage (or source voltage) is applied.

The gate electrode 42 includes an upper surface 42A, which is covered by the insulation layer 14, and a bottom surface 42B opposite to the upper surface 42A. The field plate electrode 44 may be arranged in the gate trench 20 below the gate electrode 42. In further detail, the field plate electrode 44 is arranged between the bottom surface 42B of the gate electrode 42 and the bottom wall 20B of the gate trench 20. At least part of the bottom surface 42B of the gate electrode 42 may face the field plate electrode 44 with the insulation layer 14 located in between. The gate electrode 42 further includes a side surface 42C facing the side wall 20A of the gate trench 20.

The upper surface 42A of the gate electrode 42 may be located downward from the second surface 12B of the semiconductor layer 12. Further, the bottom surface 42B of the gate electrode 42 is located proximate to the interface of the drift region 36 and the body region 38 in the Z-axis direction, preferably, downward from the interface. The upper surface 42A and the bottom surface 42B of the gate electrode 42 may be flat or curved.

The gate electrode 42 and the field plate electrode 44 are surrounded by the insulation layer 14. The field plate electrode 44 may have a smaller width than the gate electrode 42. When the field plate electrode 44 has a relatively small width, the insulation layer 14 surrounding the field plate electrode 44 will be relatively thick. This mitigates electric field concentration in the gate trench 20.

The insulation layer 14 includes a gate insulation portion 46 that is located between the gate electrode 42 and the semiconductor layer 12 and covers the side wall 20A of the gate trench 20. The gate insulation portion 46 is a part of the insulation layer 14 that is located between the side surface 42C of the gate electrode 42 and the side wall 20A of the gate trench 20. The gate insulation portion 46 is in contact with both the side surface 42C of the gate electrode 42 and the side wall 20A of the gate trench 20. Thus, the gate electrode 42 faces the semiconductor layer 12 with the gate insulation portion 46 located in between. When a predetermined voltage is applied to the gate electrode 42, a channel forms in the p-type body region 38, which is adjacent to the gate insulation portion 46. The semiconductor device 10 allows for control of the flow of electrons through the channel between the n-type source region 40 and the n-type drift region 36 in the Z-axis direction.

The semiconductor layer 12 may further include contact regions 48. The contact regions 48 may be p-type regions containing P-type impurities. The contact regions 48 may have a p-type impurity concentration in a range from 1×10¹⁹ cm⁻³ to 1×10²¹ cm⁻³, inclusive, which is higher than that of the body region 38. Each source contact plug 24 extends through the insulation layer 14 and the source region 40 and contacts a corresponding one of the contact regions 48. Thus, the source contact plugs 24 electrically connect the source interconnection 18, which is formed on the insulation layer 14, to the contact regions 48 of the semiconductor layer 12.

The semiconductor device 10 may further include a drain electrode 50 formed on the first surface 12A of the semiconductor layer 12. The drain electrode 50 is located adjacent to and is electrically connected to the drain region (semiconductor substrate 32). The drain electrode 50 may be formed from at least one of titanium (Ti), nickel (Ni), gold (Au), silver (Ag), copper (Cu), aluminum (Al), a copper alloy, and an aluminum alloy.

### Details of Gate Electrode

The gate electrode 42 includes a first conductive portion 52 and a second conductive portion 54, which includes a side surface 54A contacting the first conductive portion 52. The second conductive portion 54 may be embedded in a recess 52A formed in the first conductive portion 52. The first conductive portion 52 includes the side surface 42C and the bottom surface 42B of the gate electrode 42. Part of the upper surface 42A of the gate electrode 42 is included in the second conductive portion 54, and the remaining part of the upper surface 42A of the gate electrode 42 is included in the first conductive portion 52.

The first conductive portion 52 is in contact with the gate insulation portion 46. In further detail, the first conductive portion 52 contacts the gate insulation portion 46 at the side surface 42C of the gate electrode 42. Thus, the first conductive portion 52 faces the body region 38 of the semiconductor layer 12 with the gate insulation portion 46 located in between.

The first conductive portion 52 is formed from polysilicon, and the second conductive portion 54 is formed from metal. The second conductive portion 54 may be formed from a metal including at least one of tungsten (W), titanium (Ti), titanium nitride (TiN), and nickel (Ni). For example, the second conductive portion 54 may include titanium nitride, serving as a barrier metal, and tungsten, serving as an embedded metal. In this case, titanium nitride may be applied along the wall of the recess 52A in the first conductive portion 52, and tungsten may be embedded in the titanium nitride. The application of titanium nitride along the wall of the recess 52A prevents the diffusion of tungsten in the first conductive portion 52 (polysilicon).

In general, metal is a material having a lower resistivity than polysilicon. Thus, the second conductive portion 54 has a lower resistivity than the first conductive portion 52. The polysilicon may be doped with impurities.

The field plate electrode 44 may be formed from polysilicon. In another example, the field plate electrode 44 may be formed from metal. In such a case, the field plate electrode 44 may be formed from the same metal as the second conductive portion 54.

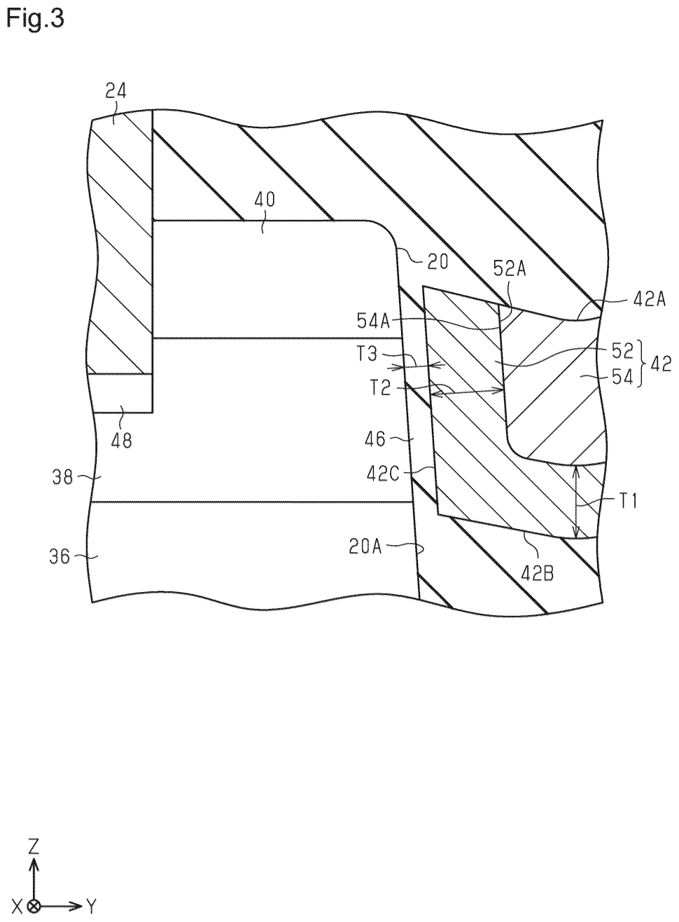

With reference to FIG. 3, the dimensions of the first conductive portion 52 will now be described. FIG. 3 is a partially enlarged view of FIG. 2. As illustrated in FIG. 3, the first conductive portion 52 has a thickness expressed by T1 between the bottom surface 42B of the gate electrode 42 and the second conductive portion 54, and the first conductive portion 52 has a thickness expressed by T2 between the side surface 42C of the gate electrode 42 and the second conductive portion 54. Thickness T1 corresponds to the distance between the bottom surface 42B of the gate electrode 42 and the second conductive portion 54. Thickness T1 is a dimension taken in the Z-axis direction. Thickness T2 corresponds to the distance between the side surface 42C of the gate electrode 42 and the second conductive portion 54 (side surface 54A). Thickness T2 is a dimension taken in a direction orthogonal to the side surface 42C. In the present specification, thickness T1 is also referred to as the bottom thickness T1 of the first conductive portion 52, and thickness T2 is also referred to as the side thickness T2 of the first conductive portion 52.

The gate insulation portion 46 has a thickness expressed by T3. Thickness T3 corresponds to the distance between the side wall 20A of the gate trench 20 and the side surface 42C of the gate electrode 42. Thickness T3 is a dimension taken in a direction orthogonal to the side wall 20A.

The bottom thickness T1 of the first conductive portion 52 may be the same as the side thickness T2 of the first conductive portion 52. More preferably, the bottom thickness T1 of the first conductive portion 52 may be less than the side thickness T2 of the first conductive portion 52. The first conductive portion 52, which is formed from polysilicon, has a higher resistivity than the second conductive portion 54, which is formed from metal. Thus, the bottom thickness T1 of the first conductive portion 52 may be decreased to lower the gate resistance of the semiconductor device 10. Accordingly, the bottom thickness T1 of the first conductive portion 52 may be as small as possible. For example, the bottom thickness T1 of the first conductive portion 52 may be less than or equal to the thickness T3 of the gate insulation portion 46.

In addition to the bottom thickness T1 of the first conductive portion 52, the side thickness T2 of the first conductive portion 52 may be decreased to further lower the gate resistance of the semiconductor device 10. When, however, the side thickness T2 of the first conductive portion 52 is overly decreased, the gate threshold voltage of the semiconductor device 10 may be affected. Accordingly, the side thickness T2 of the first conductive portion 52 may be set while taking into consideration both the gate resistance and the gate threshold voltage. The side thickness T2 of the first conductive portion 52 may be greater than the thickness T3 of the gate insulation portion 46.

### Arrangement of Gate Contact Plugs

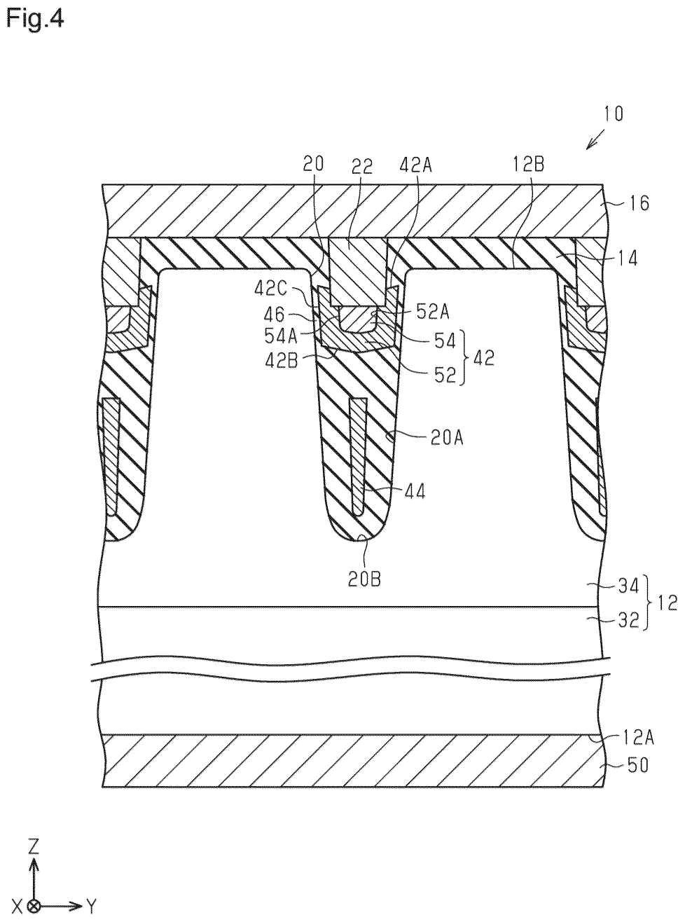

With reference to FIG. 4, the arrangement of the gate contact plugs 22 will now be described. FIG. 4 is a schematic cross-sectional view of the semiconductor device 10 taken along line F4-F4 in FIG. 1. FIG. 4 differs from FIG. 3 in that it shows the cross section of a region where the gate interconnection 16 is formed on the insulation layer 14.

The gate contact plugs 22 are configured to connect the gate interconnection 16 to the corresponding gate electrodes 42. Each gate contact plug 22 extends through the insulation layer 14 between the upper surface 42A of the corresponding gate electrode 42 and the gate interconnection 16. In the example of FIG. 4, each gate contact plug 22 has a width in the Y-axis direction that is smaller than that of the gate electrode 42 but greater than that of the second conductive portion 54. Thus, the gate contact plug 22 is in contact with the first conductive portion 52 and the second conductive portion 54.

### Operation

The operation of the semiconductor device 10 of the present embodiment will now be described.

In the semiconductor device 10 of the present embodiment, the gate electrode 42 includes the first conductive portion 52, which contacts the gate insulation portion 46, and the second conductive portion 54, which includes the side surface 54A contacting the first conductive portion 52. The first conductive portion 52 is formed from polysilicon, and the second conductive portion 54 is formed from metal.

In general, metal is a material having a lower resistivity than polysilicon. Thus, the gate electrode 42 including the second conductive portion 54, which is formed from metal, lowers the gate resistance of the semiconductor device 10.

The gate threshold voltage of the semiconductor device 10 is affected by the relationship of the work functions (energy difference of vacuum level and Fermi level) between the materials at opposite sides of the gate insulation portion 46. In the semiconductor device 10, the body region 38 of the semiconductor layer 12 faces the gate electrode 42 with the gate insulation portion 46 located in between. Thus, the relationship of the work function of the material forming the body region 38 of the semiconductor layer 12 (silicon containing p-type impurities in present embodiment) and the work function of the material forming the gate electrode 42 affects the gate threshold voltage. For example, when the gate electrode 42 is entirely formed from metal, the gate resistance will decrease but the gate threshold voltage will change from that when the gate electrode 42 is formed from polysilicon.

In the semiconductor device 10 of the present embodiment, the first conductive portion 52 is in contact with the gate insulation portion 46, and the first conductive portion 52 faces the semiconductor layer 12 (body region 38) with the gate insulation portion 46 located in between. Thus, even though the gate electrode 42 includes the second conductive portion 54 that is formed from metal, the first conductive portion 52 is formed from polysilicon and limits changes in the gate threshold voltage.

### Advantages

The semiconductor device 10 of the present embodiment has the advantages described below.
(1) Each gate electrode 42 includes the first conductive portion 52, which contacts the gate insulation portion 46, and the second conductive portion 54, which includes the side surface 54A contacting the first conductive portion 52. The first conductive portion 52 is formed from polysilicon, and the second conductive portion 54 is formed from metal. This allows the gate resistance to be lowered, while limiting changes in the gate threshold voltage.
(2) The thickness T1 of the first conductive portion 52 between the bottom surface 42B of the gate electrode 42 and the second conductive portion 54 may be less than the thickness T2 of the first conductive portion 52 between the side surface 42C of the gate electrode 42 and the second conductive portion 54.

When the thickness T2 of the first conductive portion 52 between the side surface 42C of the gate electrode 42 and the second conductive portion 54 is overly decreased, the gate threshold voltage may be affected. In contrast, even when the thickness T1 of the first conductive portion 52 between the bottom surface 42B of the gate electrode 42 and the second conductive portion 54 is decreased, the effect on the gate threshold voltage will be small. Thus, by setting thickness T1 to be less than thickness T2, the gate resistance may be further lowered, while limiting changes in the gate threshold voltage.
(3) The thickness T2 of the first conductive portion 52 between the side surface 42C of the gate electrode 42 and the second conductive portion 54 may be greater than the thickness T3 of the gate insulation portion 46.

When the thickness T2 of the first conductive portion 52 between the side surface 42C of the gate electrode 42 and the second conductive portion 54 is overly decreased, the gate threshold voltage may be affected. Thus, the thickness T3 of the gate insulation portion 46 may be increased to limit changes in the gate threshold voltage.
(4) The semiconductor device 10 may include the field plate electrode 44 located below the gate electrode 42 in each gate trench 20.

This allows the breakdown voltage to be maintained even when the impurity concentration of the epitaxial layer 34 is increased to lower the on resistance of the semiconductor device 10. Further, the gate-drain capacitance can be decreased. This allows the switching speed of the semiconductor device 10 to be increased.

### Second Embodiment

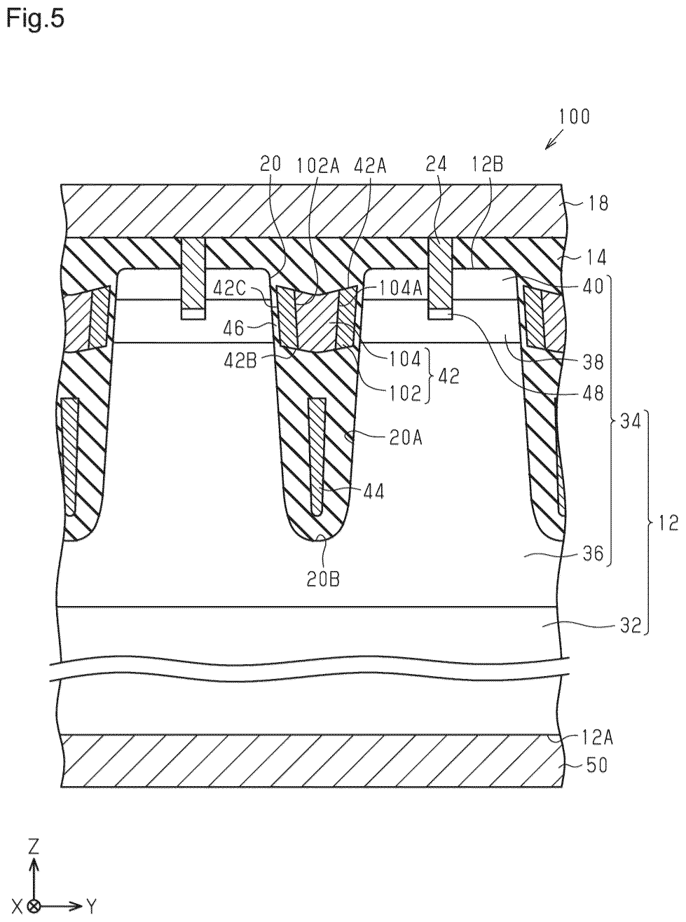

FIG. 5 is a schematic cross-sectional view of an exemplary semiconductor device 100 in accordance with a second embodiment. In FIG. 5, same reference characters are given to those elements that are the same as the corresponding elements in the semiconductor device 10. Elements that are the same as the corresponding elements of the semiconductor device 10 will not be described in detail.

In the semiconductor device 100, each gate electrode 42 includes a first conductive portion 102, which is formed from polysilicon, and a second conductive portion 104, which is formed from metal. The first conductive portion 102 is in contact with the gate insulation portion 46. Further, the second conductive portion 104 includes a side surface 104A that contacts the first conductive portion 102. The second conductive portion 104 differs from the second conductive portion 54 of the first embodiment in that it extends from the upper surface 42A to the bottom surface 42B of the gate electrode 42. The first conductive portion 102 includes an opening 102A extending from the upper surface 42A to the bottom surface 42B of the gate electrode 42. The second conductive portion 104 is embedded in the opening 102A.

The ratio of the second conductive portion 104 in the gate electrode 42 is increased from the first embodiment. Thus, the semiconductor device 100 allows the gate resistance to be further lowered, while limiting changes in the gate threshold voltage.

### Third Embodiment

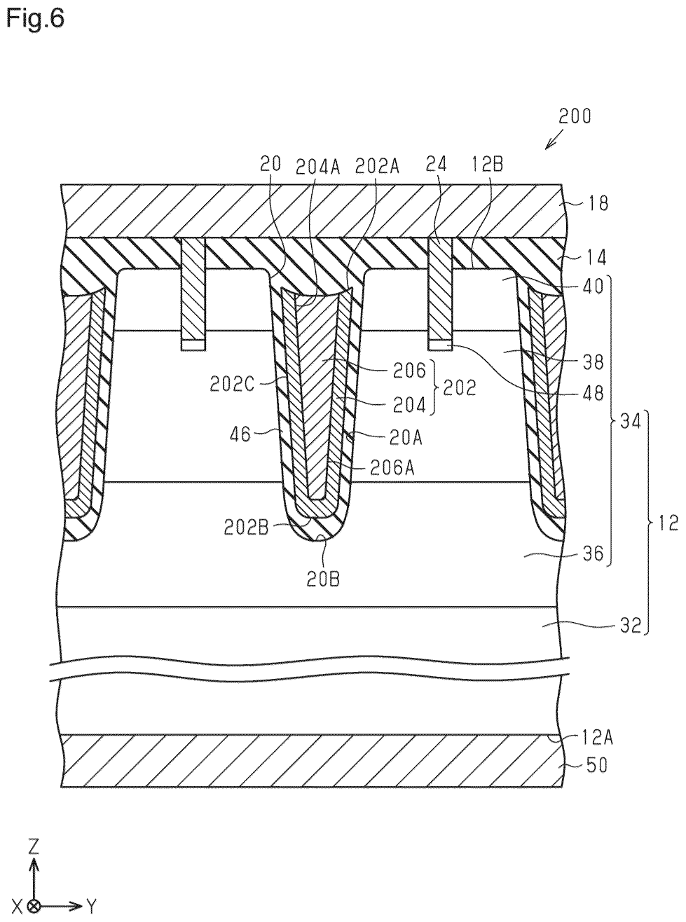

FIG. 6 is a schematic cross-sectional view of an exemplary semiconductor device 200 in accordance with a third embodiment. In FIG. 6, same reference characters are given to those elements that are the same as the corresponding elements in the semiconductor device 10. Elements that are the same as the corresponding elements of the semiconductor device 10 will not be described in detail.

The semiconductor device 200 includes a gate electrode 202 arranged in each gate trench 20. This embodiment differs from the first and second embodiments in that there is no electrode below the gate electrode 202.

The gate electrode 202 includes an upper surface 202A, which is covered by the insulation layer 14, and a bottom surface 202B opposite to the upper surface 202A. The bottom surface 202B of the gate electrode 202 faces the bottom wall 20B of the gate trench 20 with the insulation layer 14 located in between. The gate electrode 202 further includes a side surface 202C facing the side wall 20A of the gate trench 20.

The upper surface 202A of the gate electrode 202 may be located downward from the second surface 12B of the semiconductor layer 12. Further, the bottom surface 202B of the gate electrode 202 may be located downward in the Z-axis direction from the interface of the drift region 36 and the body region 38. The upper surface 202A and the bottom surface 202B of the gate electrode 202 may be flat or curved.

The gate electrode 202 is surrounded by the insulation layer 14. The insulation layer 14 includes the gate insulation portion 46 that is located between the gate electrode 202 and the semiconductor layer 12 and covers the side wall 20A of the gate trench 20. The gate insulation portion 46 is a part of the insulation layer 14 that is located between the side surface 202C of the gate electrode 202 and the side wall 20A of the gate trench 20. The gate insulation portion 46 is in contact with both the side surface 202C of the gate electrode 202 and the side wall 20A of the gate trench 20. When a predetermined voltage is applied to the gate electrode 202, a channel forms in the p-type body region 38, which is adjacent to the gate insulation portion 46. The semiconductor device 200 allows for control of the flow of electrons through the channel between the n-type source region 40 and the n-type drift region 36 in the Z-axis direction.

The gate electrode 202 includes a first conductive portion 204 and a second conductive portion 206, which includes a side surface 206A contacting the first conductive portion 204. The second conductive portion 206 may be embedded in a recess 204A formed in the first conductive portion 204. The first conductive portion 204 includes the side surface 202C and the bottom surface 202B of the gate electrode 202. Part of the upper surface 202A of the gate electrode 202 is included in the second conductive portion 206, and the remaining part of the upper surface 202A of the gate electrode 202 is included in the first conductive portion 204.

The first conductive portion 204 is in contact with the gate insulation portion 46. In further detail, the first conductive portion 204 contacts the gate insulation portion 46 at the side surface 202C of the gate electrode 202.

The first conductive portion 204 is formed from polysilicon, and the second conductive portion 206 is formed from metal. The second conductive portion 206 may be formed from a metal including at least one of tungsten (W), titanium (Ti), titanium nitride (TiN), and nickel (Ni). For example, the second conductive portion 206 may include titanium nitride, serving as a barrier metal, and tungsten, serving as an embedded metal. In this case, titanium nitride may be applied along the wall of the recess 204A in the first conductive portion 204, and tungsten may be embedded in the titanium nitride. The application of titanium nitride along the wall of the recess 204A prevents the diffusion of tungsten in the first conductive portion 204 (polysilicon).

In general, metal is a material having a lower resistivity than polysilicon. Thus, the second conductive portion 206 has a lower resistivity than the first conductive portion 204. The polysilicon may be doped with impurities.

A thickness of the first conductive portion 204 between the bottom surface 202B of the gate electrode 202 and the second conductive portion 206 may be the same as a thickness of the first conductive portion 204 between the side surface 202C of the gate electrode 202 and the second conductive portion 206. To further lower the gate resistance, the thickness of the first conductive portion 204 between the bottom surface 202B of the gate electrode 202 and the second conductive portion 206 may be less than the thickness of the first conductive portion 204 between the side surface 202C of the gate electrode 202 and the second conductive portion 206. Alternatively, to facilitate the embedding of the second conductive portion 206 in the recess 204A of the first conductive portion 204, the thickness of the first conductive portion 204 between the bottom surface 202B of the gate electrode 202 and the second conductive portion 206 may be greater than the thickness of the first conductive portion 204 between the side surface 202C of the gate electrode 202 and the second conductive portion 206. This is because when the thickness of the first conductive portion 204 increases between the bottom surface 202B of the gate electrode 202 and the second conductive portion 206, the depth of the recess 204A decreases in the first conductive portion 204.

The thickness of the first conductive portion 204 between the side surface 202C of the gate electrode 202 and the second conductive portion 206 may be decreased to further lower the gate resistance of the semiconductor device 200. When, however, the thickness of the first conductive portion 204 between the side surface 202C of the gate electrode 202 and the second conductive portion 206 is overly decreased, the gate threshold voltage of the semiconductor device 200 may be affected. Thus, the thickness of the first conductive portion 204 between the side surface 202C of the gate electrode 202 and the second conductive portion 206 should be greater than the thickness of the gate insulation portion 46.

In this manner, the gate electrode 202 includes the first conductive portion 204, which is formed from polysilicon and which contacts the gate insulation portion 46, and the second conductive portion 206, which includes the side surface 206A contacting the first conductive portion 204. Accordingly, in the same manner as the first embodiment, the third embodiment allows the gate resistance to be lowered, while limiting changes in the gate threshold voltage.

### MODIFIED EXAMPLES

The above-described embodiments may be modified as described below.

### Modified Example of Gate Electrode

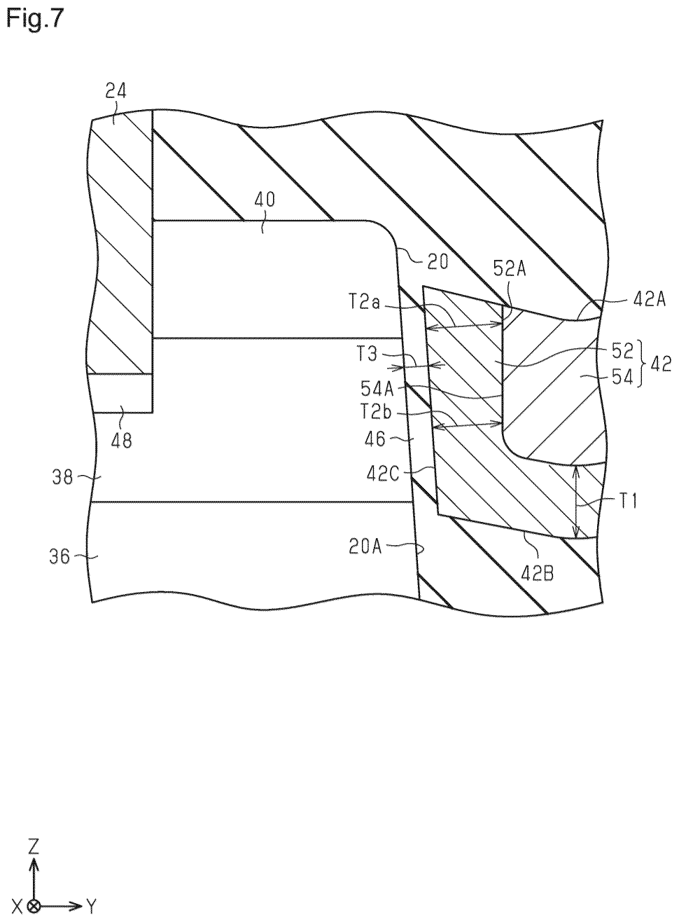

The first conductive portion 52 and the second conductive portion 54 in the first embodiment may have any shape. FIG. 7 is an enlarged cross-sectional view showing the gate electrode 42 in which the side surface 54A of the second conductive portion 54 is not parallel to the side surface 42C of the gate electrode 42.

The side surface 42C of the gate electrode 42 may be substantially parallel to the side wall 20A. As shown in the example of FIG. 7, when the side wall 20A of the gate trench 20 is inclined relative to the Z-axis direction and the side surface 54A of the second conductive portion 54 extends in the Z-axis direction, the side thickness T2 of the first conductive portion 52 decreases as the bottom surface 42B of the gate electrode 42 becomes closer. For example, a side thickness T2b at a position close to the bottom surface 42B of the gate electrode 42 is less than a side thickness T2a at a position close to the upper surface 42A of the gate electrode 42.

As described above, when the side thickness T2 of the first conductive portion 52 is overly decreased, the gate threshold voltage of the semiconductor device 10 may be affected. When the side thickness T2 is not uniform as in the example of FIG. 7, the first conductive portion 52 may be formed so that the part where the thickness T2 is the smallest is thick enough so as not to affect the gate threshold voltage.

### Modified Example of Gate Contact Plug

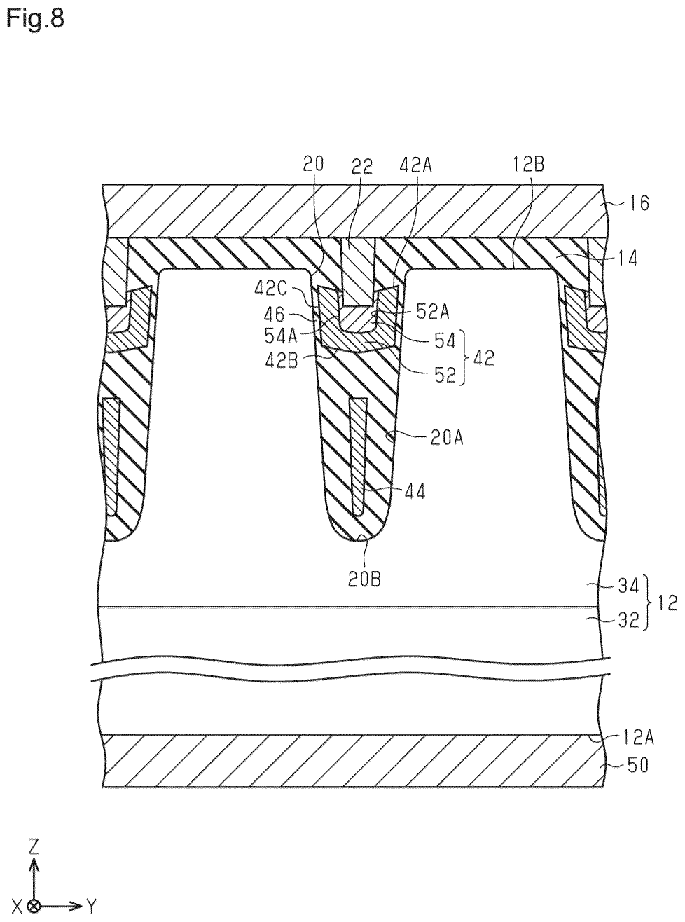

In each of the above embodiments, the gate contact plugs 22 may be dimensioned in any manner. FIG. 8 shows the arrangement of the gate contact plugs 22 on the gate electrodes 42 when the gate contact plugs 22 have a relatively small width.

In the example of FIG. 8, each gate contact plug 22 has a width in the Y-axis direction that is less than the width of the corresponding gate electrode 42 and less than the width of the second conductive portion 54. In this case, the bottom of the gate contact plug 22 is in contact with the second conductive portion 54 but not with the first conductive portion 52. For example, when the gate contact plug 22 and the second conductive portion 54 both include TiN, as a barrier metal, and W, as an embedded metal, the W included in the second conductive portion 54 may be in contact with the TiN included in the gate contact plug 22.

### Other Modified Examples

In the third embodiment, the second conductive portion 206 may extend from the upper surface 202A to the bottom surface 202B of the gate electrode 202. This further lowers the gate resistance, while limiting changes in the gate threshold voltage.

The conductivity type of each region in the semiconductor layer 12 may be inverted. That is, the p-type region may be an n-type region, and the n-type region may be a p-type region.

One or more of the various examples described in this specification may be combined as long as there is no technical contradiction.

In this specification, “at least one of A and B” should be understood to mean “only A, only B, or both A and B.”

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is arranged above the second layer without contacting the second layer in another embodiment. Thus, the word “on” will also allow for a structure in which another layer is arranged between the first layer and the second layer.

The terms used in this specification to indicate directions such as vertical, horizontal, upward, downward, up, down, forward, rearward, side, left, right, front, and back will be attributed to specific directions of the described and illustrated device. In this disclosure, a variety of alternative directions may be available for any given direction. Thus, directional terms should not be construed narrowly.

For example, the Z-axis direction as referred to in this specification does not necessarily have to be the vertical direction and does not necessarily have to fully coincide with the vertical direction. For example, the X-axis direction may be the vertical direction. Alternatively, the Y-axis direction may be the vertical direction.

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### [Clause 1]

A semiconductor device, including:
a semiconductor layer (12);
a trench (20) formed in the semiconductor layer (12) and including a side wall (20A);
an insulation layer (14) formed on the semiconductor layer (12); and
a gate electrode (42) arranged in the trench (20), where
the insulation layer (14) includes a gate insulation portion (46) located between the semiconductor layer (12) and the gate electrode (42), and covering the side wall (20A) of the trench (20),
the gate electrode (42) includes
   a first conductive portion (52) contacting the gate insulation portion (46), and
   a second conductive portion (54) including a side surface (54A) contacting the first conductive portion (52), and
the first conductive portion (52) is formed from polysilicon, and the second conductive portion (54) is formed from metal.

### [Clause 2]

The semiconductor device according to clause 1, where
the gate electrode (42) includes a side surface (42C) facing the side wall (20A) of the trench (20), and the first conductive portion (52) includes the side surface (42C) of the gate electrode (42).

### [Clause 3]

The semiconductor device according to clause 1 or 2, where the second conductive portion (54) is embedded in a recess (52A) formed in the first conductive portion (52).

### [Clause 4]

The semiconductor device according to any one of clauses 1 to 3, where the gate electrode (42) includes an upper surface (42A) covered by the insulation layer (14).

### [Clause 5]

The semiconductor device according to clause 4, where the second conductive portion (54) includes a part of the upper surface (42A) of the gate electrode (42).

### [Clause 6]

The semiconductor device according to clause 4 or 5, where
the gate electrode (42) includes a bottom surface (42B) opposite to the upper surface (42A), and
the first conductive portion (52) includes the bottom surface (42B) of the gate electrode (42).

### [Clause 7]

The semiconductor device according to clause 4 or 5, where
the gate electrode (42) includes a bottom surface (42B) opposite to the upper surface (42A), and
the second conductive portion (104) extends from the upper surface (42A) to the bottom surface (42B) of the gate electrode (42).

### [Clause 8]

The semiconductor device according to clause 6, where a thickness (T1) of the first conductive portion (52) between the bottom surface (42B) of the gate electrode (42) and the second conductive portion (54) is less than a thickness (T2) of the first conductive portion (52) between the side surface (42C) of the gate electrode (42) and the second conductive portion (54).

### [Clause 9]

The semiconductor device according to clause 8, where the thickness (T1) of the first conductive portion (52) between the bottom surface (42B) of the gate electrode (42) and the second conductive portion (54) is less than or equal to a thickness (T3) of the gate insulation portion (46).

### [Clause 10]

The semiconductor device according to any one of clauses 4 to 9, further including:
a gate interconnection (16) formed on the insulation layer (14); and
a gate contact plug (22) configured to couple the gate interconnection (16) to the gate electrode (42),
where the gate contact plug (22) extends through the insulation layer (14) between the upper surface (42A) of the gate electrode (42) and the gate interconnection (16), and contacts the first conductive portion (52) and the second conductive portion (54).

### [Clause 11]

The semiconductor device according to any one of clauses 1 to 10, where a thickness (T2) of the first conductive portion (52) between the side surface (42C) of the gate electrode (42) and the second conductive portion (54) is greater than a thickness (T3) of the gate insulation portion (46).

### [Clause 12]

The semiconductor device according to any one of clauses 1 to 11, where the second conductive portion (54) is formed from a metal including at least one of tungsten, titanium, titanium nitride, and nickel.

### [Clause 13]

The semiconductor device according to any one of clauses 1 to 12, further including a field plate electrode (44) located below the gate electrode (42) in the trench (20).

### [Clause 14]

The semiconductor device according to clause 13, where the field plate electrode (44) is formed from polysilicon.

### [Clause 15]

The semiconductor device according to any one of claims 1 to 14, where the semiconductor layer (12) includes a drift region (36) of a first conductivity type, a body region (38) of a second conductivity type formed on the drift region (36), and a source region (40) of a first conductivity type formed on the body region (38), the first conductive portion (52) facing the body region (38) with the gate insulation portion (46) located in between.

Exemplary descriptions are given above. In addition to the elements and methods (manufacturing processes) described to illustrate the technology of this disclosure, a person skilled in the art would recognize the potential for a wide variety of combinations and substitutions. All variations within the scope of the claims and their equivalents are included in the disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a semiconductor layer;
a trench formed in the semiconductor layer and including a side wall;
an insulation layer formed on the semiconductor layer; and
a gate electrode arranged in the trench, wherein
the insulation layer includes a gate insulation portion located between the semiconductor layer and the gate electrode, and covering the side wall of the trench,
the gate electrode includes
a first conductive portion contacting the gate insulation portion, and
a second conductive portion including a side surface contacting the first conductive portion, and
the first conductive portion is formed from polysilicon, and the second conductive portion is formed from metal.

2. The semiconductor device according to claim 1, wherein
the gate electrode includes a side surface facing the side wall of the trench, and
the first conductive portion includes the side surface of the gate electrode.

3. The semiconductor device according to claim 1, wherein the second conductive portion is embedded in a recess formed in the first conductive portion.

4. The semiconductor device according to claim 1, wherein the gate electrode includes an upper surface covered by the insulation layer.

5. The semiconductor device according to claim 4, wherein the second conductive portion includes a part of the upper surface of the gate electrode.

6. The semiconductor device according to claim 4, wherein
the gate electrode includes a bottom surface opposite to the upper surface, and
the first conductive portion includes the bottom surface of the gate electrode.

7. The semiconductor device according to claim 4, wherein
the gate electrode includes a bottom surface opposite to the upper surface, and
the second conductive portion extends from the upper surface to the bottom surface of the gate electrode.

8. The semiconductor device according to claim 6, wherein a thickness of the first conductive portion between the bottom surface of the gate electrode and the second conductive portion is less than a thickness of the first conductive portion between the side surface of the gate electrode and the second conductive portion.

9. The semiconductor device according to claim 8, wherein the thickness of the first conductive portion between the bottom surface of the gate electrode and the second conductive portion is less than or equal to a thickness of the gate insulation portion.

10. The semiconductor device according to claim 4, further comprising
a gate interconnection formed on the insulation layer; and
a gate contact plug configured to couple the gate interconnection to the gate electrode,
wherein the gate contact plug extends through the insulation layer between the upper surface of the gate electrode and the gate interconnection, and contacts the first conductive portion and the second conductive portion.

11. The semiconductor device according to claim 1, wherein a thickness of the first conductive portion between the side surface of the gate electrode and the second conductive portion is greater than a thickness of the gate insulation portion.

12. The semiconductor device according to claim 1, wherein the second conductive portion is formed from a metal including at least one of tungsten, titanium, titanium nitride, and nickel.

13. The semiconductor device according to claim 1, further comprising a field plate electrode located below the gate electrode in the trench.

14. The semiconductor device according to claim 13, wherein the field plate electrode is formed from polysilicon.

15. The semiconductor device according to claim 1, wherein the semiconductor layer includes a drift region of a first conductivity type, a body region of a second conductivity type formed on the drift region, and a source region of a first conductivity type formed on the body region, the first conductive portion facing the body region with the gate insulation portion located in between.
